(19) United States
(12) Patent Application Publication
(10) Pub. No.: US 2026/0126726 A1
(43) Pub. Date: May 7, 2026

(54) Block Copolymers for Directed Self-Assembly and Applications in Lithography

(71) Applicant: The University of Chicago, Chicago, IL (US)

(72) Inventor: Paul Franklin NEALEY, Chicago, IL (US)

(73) Assignee: The University of Chicago, Chicago, IL (US)

(21) Appl. No.: 18/939,639

(22) Filed: Nov. 7, 2024

Related U.S. Application Data
(60) Provisional application No. 63/596,888, filed on Nov. 7, 2023.

(51) Int. Cl. G03F 7/038; G03F 7/00

(52) U.S. Cl. CPC G03F 7/038; G03F 7/70033

(57) ABSTRACT

Provided herein are block copolymer (BCP) materials for nanoscale patterning and related methods. In some embodiments, the BCPs are based on polypeptoids, achieving protein-like functionality in synthetic materials for manufacturing at the nanoscale. Zero dispersity BCPs and related methods of designing and high-volume synthesis are provided.

### INCORPORATION BY REFERENCE

An Application Data Sheet is filed concurrently with this specification as part of the present application. Each application that the present application claims the benefit of or priority to as identified in the concurrently filed Application Data Sheet is incorporated by reference herein in its entirety and for all purposes.

### BACKGROUND

In EUV lithography, imaging materials are exposed to high energy photons with a wavelength of 13.5 nm photons. Radiation chemistry (rather than traditional functional group photochemistry) governs the exposure induced chemical reactions in resists that result in high contrast in dissolution between exposed and unexposed regions. The stochastic nature of energy deposition in the resist results in process and pattern non-uniformity. Despite the dramatic differences between photochemistry-based lithography and radiation chemistry-based lithography (such as EUV and electron beam lithography), chemically amplified resists designed for photochemistry remain the most heavily employed resists for EUV. It is unlikely that these resists can meet manufacturing requirements in terms of pattern quality, sensitivity, and throughput below 24 nm full pitch.

Another challenge for EUV imaging materials and patterning processes is patterning in high volume manufacturing at the molecular length scale (single digit nanometer dimensions) with tolerances and margins requiring atomic level precision (<1 nm). Current EUV tools are capable of 24 nm full pitch. High numerical aperture (NA) EUV tools capable of 16 nm full pitch and ‘hyper’ NA EUV that can deliver exposure contrast at 8 nm full pitch are on the horizon. Unconventional metal oxide-based resists show potential at 16 nm full pitch in terms of resolution but have not yet been shown to meet all manufacturing constraints including resolution, sensitivity/throughput, pattern quality, and process integration. It may be difficult for any resist to perform all the functions of patterning with scalability to 8 nm full pitch in EUV lithography: high contrast in image development at manufacturing relevant exposure dose, stringent requirements related to atomic level precision in feature size and shape, and effective pattern transfer properties.

### SUMMARY

Provided herein are block copolymer (BCP) materials for nanoscale patterning and related methods. In some embodiments, the BCPs are based on polypeptoids, achieving protein-like functionality in synthetic materials for manufacturing at the nanoscale. Zero dispersity BCPs and related methods of designing and high-volume synthesis are provided.

Sequence and composition specific BCPs with zero dispersity made in quantity using solid-phase synthesis enable control over material properties and enable reproducibility in the production and application specific uses for manufacturing at the single nanometer length scale with angstrom scale tolerances and margins.

One aspect of the disclosure relates to a method including forming a BCP system including A-(B-r-C) block copolymer (BCP) molecules, the BCP molecules each including an A block and a (B-r-C) block, wherein the (B-r-C) block is polypeptoid copolymer; wherein surface energies of the A and (B-r-C) blocks are commensurate with each other such that the BCP system can assemble in a thin film with non-preferential wetting of domains of the A and (B-r-C) blocks at the surface or interface of the thin film. The A-(B-r-C) block copolymer (BCP) molecules are monodisperse in some embodiments. This may be characterized by a dispersity Ð_{M}=M_{w}/Mₙ of 1. In some embodiments, the A block is a peptoid. In some embodiments, the A block is a non-peptoid.

Another aspect of the disclosure includes predicting an interfacial width of an assembled thin film and surface energies based on only the sequence of monomers and their chemical identities. A machine learning model may be used. In some embodiments, the methods include training the model.

Another aspect of the disclosure is spin coating or otherwise forming a composition including a BCP system including A-(B-r-C) block copolymer (BCP) molecules on a patterned substrate, wherein the BCP molecules each include an A block and a (B-r-C) block and the (B-r-C) block is polypeptoid copolymer. The method can further include inducing directed assembly of the BCP in accordance with the pattern. The pattern may be transferred to the substrate. Examples of substrates include silicon substrates. The BCPs molecules may be monodisperse.

These and other aspects of the disclosure are described below with the reference to the drawings.

### BRIEF DESCRIPTION OF DRAWINGS

FIG. 1 shows an example of a patterning workflow that uses lithography and directed self-assembly (DSA) of block copolymers (BCPs).

FIG. 2 shows an example of an iterative solid-phase synthetic cycle for peptoids.

FIG. 3A shows examples of methods to synthesize a hybrid peptoid BCP.

FIG. 3B shows examples of methods to synthesize an all peptoid BCP.

FIG. 4 shows schematic examples of variables to tune the self-assembly behavior.

FIG. 5 shows examples of side chain groups that can be incorporated into a peptoid BCP.

FIG. 6 shows an example of a resonant soft X-ray reflectivity (RSoXR) profile and structural information that can be obtained from reflectivity experiments.

FIG. 7 shows an SEM image of an unaligned fingerprint pattern of a BCP and an example of roughness calculations that can be derived from such a pattern.

FIG. 8 shows an overview of the data flow from coarse-graining chemical species, simulation synthesis and data gathering, machine learning models and discovery of new peptoid sequences for directed self-assembly and lithography techniques.

FIG. 9 shows an example of molecular transfer printing to pattern a polymer brush on a substrate, followed by directed self-assembly of a thin film of the substrate, and pattern transfer to the substrate.

FIG. 10 shows an example of a peptoid macro-CTA synthesis.

### DETAILED DESCRIPTION

### Introduction

In EUV lithography, imaging materials are exposed to high energy photons with a wavelength of 13.5 nm photons. Radiation chemistry (rather than traditional functional group photochemistry) governs the exposure induced chemical reactions in resists that result in high contrast in dissolution between exposed and unexposed regions. The stochastic nature of energy deposition in the resist results in process and pattern non-uniformity. Despite the dramatic differences between photochemistry-based lithography and radiation chemistry-based lithography (such as EUV and electron beam lithography), chemically amplified resists designed for photochemistry remain the most heavily employed resists for EUV. It is unlikely that these resists can meet manufacturing requirements in terms of pattern quality, sensitivity, and throughput below 24 nm full pitch.

Another challenge for EUV imaging materials and patterning processes is patterning in high volume manufacturing at the molecular length scale (single digit nanometer dimensions) with tolerances and margins requiring atomic level precision (<1 nm). Current EUV tools are capable of 24 nm full pitch. High numerical aperture (NA) EUV tools capable of 16 nm full pitch and ‘hyper’ NA EUV that can deliver exposure contrast at 8 nm full pitch are on the horizon. Unconventional metal oxide-based resists show potential at 16 nm full pitch in terms of resolution but have not yet been shown to meet all manufacturing constraints including resolution, sensitivity/throughput, pattern quality, and process integration. It may be difficult for any resist to perform all the functions of patterning with scalability to 8 nm full pitch in EUV lithography: high contrast in image development at manufacturing relevant exposure dose, stringent requirements related to atomic level precision in feature size and shape, and effective pattern transfer properties.

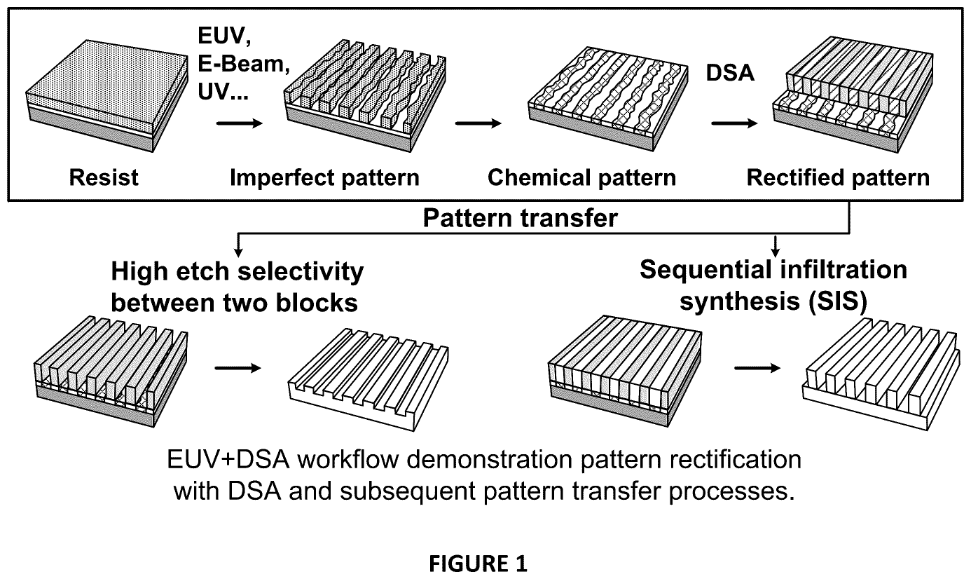

FIG. 1 shows an example of a patterning workflow that uses lithography and directed self-assembly (DSA) of BCPs to address some of these challenges. As shown in FIG. 1, the process involves patterning a resist with a lithographic tool. In many embodiments, the lithographic tool involves EUV. Other examples of tools include those using photolithography or e-beam radiation. The result is a pattern with imperfections caused by the reasons described above. The imperfections may include deviations from an ideal pattern in roughness, line width (or other appropriate feature size), line width size distributions, and point defects. The patterned resist is converted into a chemical pattern with contrast in wetting preference towards the blocks of a BCP. As shown in FIG. 1, the chemical pattern includes the imperfections. A BCP is then deposited (e.g., by spin coating) or otherwise formed on the chemical pattern.

BCPs are a class of polymers that have two or more polymeric blocks. At particular conditions and volume fraction of the constituent blocks, a BCP will self-assemble into domains of different features. For example, a diblock BCP having blocks of approximately equal volume fraction will self-assemble into lamellar domains when annealed above the glass transition temperature of the blocks. In the presence of an underlying chemical pattern, the self-assembly is directed by the chemical pattern. Information encoded into the BCP that governs molecular self-assembly (for example the interfacial energy between block) rectifies pattern quality in the assembled polymer in comparison to that of the chemically patterned template. With judicious choice and engineering of pattern chemistry and BCP chemistry and properties, the nanodomains in the BCP film can be directed to assemble with through film perpendicular structures that are subsequently amenable for pattern transfer to the underlying substrate.

FIG. 1 shows two examples of pattern transfer techniques - one that relies on high etch selectivity between the blocks to etch one block and one that uses sequential infiltration synthesis (SIS) in which one block is infiltrated with a material using sequential exposures to gases to increase etch resistance.

Using EUV-plus-DSA (also referred to as EUV-DSA) allows imaging, pattern quality, and pattern transfer functions in the lithographic process to be separated. As such, resist chemistries that provide patterns of marginal quality can be employed. The patterns should have the correct period (governed by the exposure tool) but can exhibit substantial roughness, deviations in duty cycle (width of a line with the pattern period), and defectivity.

In embodiments of the EUV-DSA methods described herein, the resist can be optimized for sensitivity and throughput with the BCP providing pattern quality, at the scale of molecular self-assembly, and pattern transfer properties to meet manufacturing constraints.

Poly(styrene-block-methyl methacrylate) (PS-PMMA) is a BCP that has attractive properties for DSA and pattern transfer. The surface energies of the PS and PMMA blocks are equal at convenient annealing temperatures, allowing for industry-friendly thermal processing, and there is sufficient etch contrast between blocks for pattern transfer. The resolution limit of PS-PMMA is at best 25 nm full pitch. Provided herein are BCPs and methods to design multiple co-varying properties of BCPs to allow for high volume manufacturing relevant EUV-plus-DSA patterning from 24 nm full pitch scalable to significantly lower, e.g., 8 nm full pitch.

In the example of FIG. 1, the BCP film has a “free surface”—that is, it is in contact with a non-condensed phase (e.g., vacuum, air, or other gas) at its top surface. Interactions with the BCP at the free surface are driven by surface energies of each block. Sandwiching a BCP between two condensed-phase (e.g., solid) substrates can make it easier to control the wetting behavior and assembly but are more complex.

BCPs with A-block-(B-random-C) (A-b-(B-r-C)) architectures can provide increased flexibility over PS-b-PMMA and allow decoupling of thermodynamics and surface energy. However, challenges of these (A-b-(B-r-C) BCPs include polydispersity. Even the most monodisperse BCPs synthesized by anionic polymerization (Ð=1.02) contain polymer molecules that are three times longer than the average in concentrations above the threshold for defectivity. In addition, the exact same polymer can never be synthesized twice, hindering supply chain issues with production lines needing consistent materials. Moreover, in (A-b-(B-r-C) architectures such as thiol-modified PS-PGMA systems, BCP properties depend on the randomness of the B-r-C block, and the composition of that block. Randomness cannot be measured or controlled, and when the degree of polymerization is low, heterogeneous mixtures result.

Provided herein is a platform to synthesize BCPs with use A-block-(B-random-C) (A-b-(B-r-C)) architectures with substantially increased flexibility for co-design materials for EUV plus DSA applications and potential commercialization. Aspects of the disclosure include design and solid-phase synthesis of polypeptoid (poly-N-substituted glycines) blocks with zero dispersity and exact composition and sequence of A, B, and C components.

Polypeptoid-based block copolymers allow engineering sequence specificity in the B-r-C block to co-design key EUV-plus-DSA properties, surface energy and the width of interfaces between blocks.

Self-assembly of BCPs can be characterized by the Flory-Huggins interaction parameter χ and degree of polymerization N. χN is related to the energy of mixing the blocks in a BCP and is inversely proportional to temperature. If χN is too low, the BCP will be disordered.

High χ and low N systems do not obey traditional BCP theory and scaling laws, allowing polypeptoid systems to be optimized for DSA applications including lithography. For example, segments in the B-r-C block that have moderate side chain length greatly enhance the sharpness of the interface between domains in comparison to those predicted from estimated effective χ parameters.

Sequence can play a strong role in determining surface energy, allowing flexibility in choice of components. In some embodiments, for example, a BCP may be designed to avoid incorporation of fluorine or to enhance etch contrast. And with a degree of polymerization of blocks below 60 or so, solid-phase synthesis of zero dispersity sequence specific polypeptoids in supply-chain relevant quantity is feasible. Zero dispersity, also referred to a monodispersity, refers to a plurality of polymer molecules all of which are the same size. Thus, an arbitrarily large number of polymer molecules, all of which are of the same size may be provided. In some embodiments, the dispersity is characterized by dispersity (Ð) also referred to as the polydispersity index (PDI). It can be calculated using the equation Ð_{M} =M_{w}/Mₙ, which is 1 for a zero dispersity system. In the embodiments herein, (Ð) may be unity for an arbitrarily large number of polymer molecules, e.g., at least 100, one thousand, ten thousand, one hundred thousand, five hundred thousand, or one million individual molecules.

In some embodiments, Ð_{M} =M_{w}/Mₙ is less than 1.01, less than 1.005, less than 1.01, or is 1.00. A zero dispersity system may have at least 100, one thousand, ten thousand, one hundred thousand, five hundred thousand, or one million individual molecules.

The polypeptoid platform is ideally suited for machine learning approaches to optimize properties. According to various embodiments, this can include acquisition of large experimental data sets and the training of models over a finite number of components and sequences.

### Polypeptoid-Based Block Copolymers: Design and Synthesis

An advantage of peptoids as a platform for sequence-controlled synthesis of polymers is the rich pool of functional groups that can be included in their side chains. Unlike peptides, where the accessible R groups are constrained by the limited number of amino acids themselves, the synthesis of peptoid repeat units in a sequential submonomer process is constrained solely by the accessibility of primary amines with appropriate functional groups.

Peptoid-based BCPs display phase separation behavior, such as the formation of lamellae, cylinders, and gyroid phases, with such behavior can be modulated by the choice of peptoid units in a peptoid block. Different morphologies, changes in order-disorder transition temperatures, and engineered interfaces can be accessed by the insertion of residues that make a non-peptoid block (e.g., polystyrene) more compatible in an otherwise strongly segregating peptoid block. Further variations can be achieved by varying the sequence of the peptoid block.

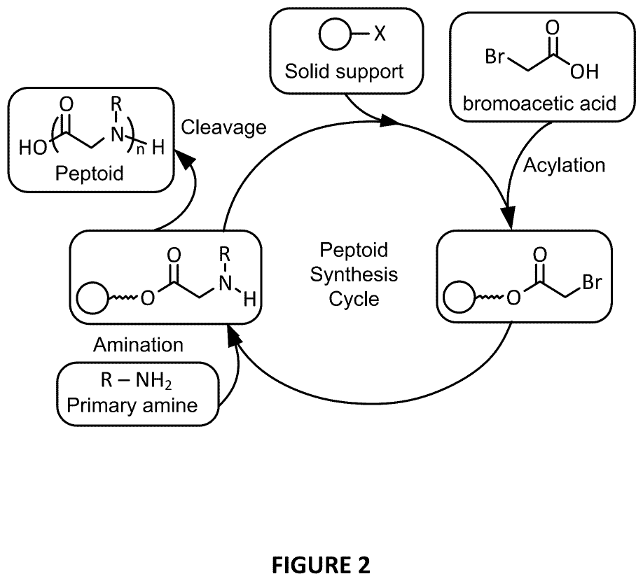

FIG. 2 shows an example of an iterative solid-phase synthetic cycle for peptoids. Bromoacetic acid is first attached to the reactive group of a resin support. The addition of a functional amine in an amination reaction forms the first repeat unit of the growing peptoid. The subsequent addition of bromoacetic acid to the amine end of the growing peptoid will restart the cycle of the monomer addition. Cleavage of the final peptoid from the solid support yields a free, monodisperse, compositionally identical and sequence-defined polypeptoid.

Once an initial peptoid block has been synthesized, a BCP can be synthesized. According to various embodiments, the BCP may be “hybrid” peptoid BCP or an all-peptoid BCP. A hybrid peptoid BCP refers to a BCP that includes at least one non-peptoid block.

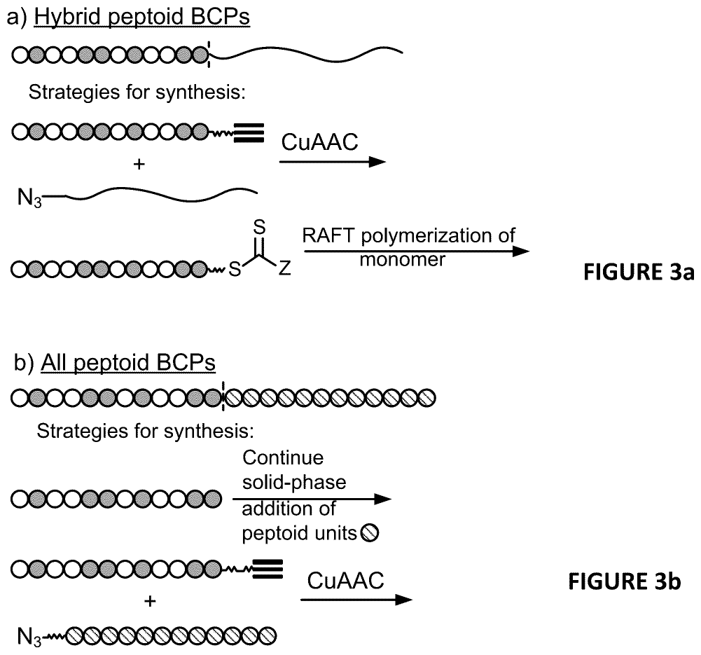

FIG. 3A shows examples of methods to synthesize a hybrid peptoid BCP. One such approach involves the chemical ligation of a peptoid and a synthesized polymer via click chemistry carried out on chain end functionalities. This method can use, for example, azide-terminated polymers and alkyne-terminated peptoids in a copper(I)-catalyzed azide-alkyne cycloaddition (CuAAC) reaction. Alternatively, a block synthesis may be performed. For example, a “peptoid macro-CTA” reaction involving a terminal chain transfer agent (CTA) amenable to reversible addition-fragmentation chain-transfer (RAFT) polymerization is attached to the end of a peptoid, from which a controlled radical polymerization can be performed to grow a second block from the peptoid. This synthesis is similar to synthesis of “peptide macro-CTAs.”

FIG. 3B shows examples of methods to synthesize an all peptoid BCP. In some embodiments, the addition of peptoid units during solid-phase synthesis onto an existing peptoid chain is continued. In another example method, peptoid chains with alkyne and azide moieties are separately synthesized, after which a CuAAC reaction ligates the two chains together to form the BCP. Such a method allows the precise sequence control afforded by the peptoid synthesis process in both blocks, while extending the limits of the potential lengths of each block, as the solid-phase synthetic approach typically reaches an upper limit of 50-60 repeat units per synthetic batch.

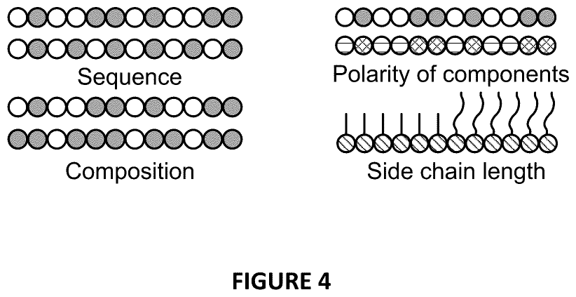

To engineer interfaces of self-assembled peptoid BCP structures, one or more of the arrangement, amount, or identity of each component of the peptoid(s) can be varied. FIG. 4 shows schematic examples of variables to tune the self-assembly behavior. Parameters that can be tuned include surface energy, segregation strength, and interfacial width. As indicated in FIG. 4, these parameters may also be affected by the polarity of components and the length of side chains.

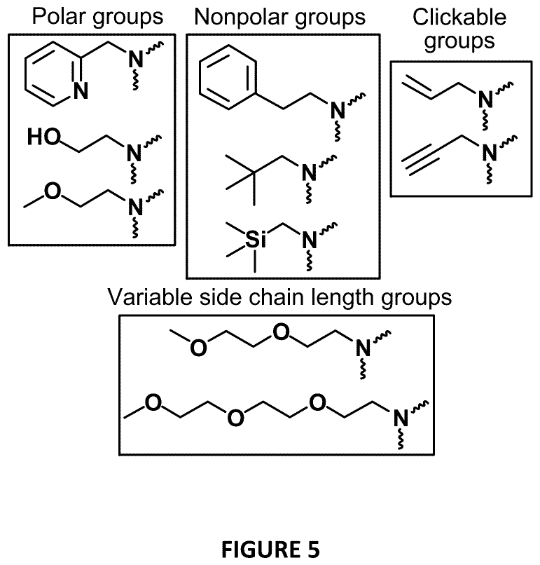

FIG. 5 shows examples of side chain groups that can be incorporated into a peptoid BCP. The components of interest may be incorporated by the array of analogous amines channeled into the solid-phase synthetic process and include those of variable polarity, side chain length, and the ability to post-synthetically modify structures via click chemistries.

In some embodiments, the peptoid BCPs are suited for pattern transfer. In some implementations, the carbonyl functionality on the backbone of a polypeptoid can be used to synthesize a peptoid BCP with useful pattern transfer or functional properties. For example, the carbonyl functionality is able to uptake precursors for atomic layer deposition (ALD) of aluminum oxide (AlOₓ). An AlOx hard-mask from within the peptoid-containing block can be formed via sequential infiltration synthesis (SIS). This SIS strategy is useful for hybrid peptoid BCP blocks in which the non-peptoid block(s) do not take up the precursor. In some embodiments, etch contrast into the BCPs by incorporating Si-containing nonpolar groups. An example is shown in FIG. 5.

In some embodiments, peptoids BCP in which the constituent blocks have commensurate surface energy are provided. Surface energy is the energy at a surface between a condensed and non-condensed phase, such as a solid BCP thin film or BCP film in the melt and a gas or vacuum. Differences in surface energies can lead to preferential wetting of one block at the surface, making pattern transfer difficult. For hybrid peptoid BCPs, the non-peptoid block(s) may incorporate a more polar polymer segment (e.g., polymethylmethacrylate (PMMA)) than polystyrene. This can mitigate surface energies differences arising the from the polarity of the amide functional groups on the peptoid backbone and a non-polar polymer such as polystyrene.

While the machine learning techniques may be used to design BCPs as described herein, other methods including trial and error may be used as appropriate.

### Characterization of Polypeptoid-Based BCPs

A-b-(B-r-C) BCPs can be characterized by length scale L₀, effective interaction parameter χ_{eff,}, and surface energy γ, to determine their suitability for DSA. One approach involves calculating L₀ as a function of Φ_{c}, the molar fraction of C in the B-r-C block. For example, transmission small angle X-ray scattering (SAXS) can be conducted on bulk samples to calculate L₀ as a function of Φ_{c}. From the measured values of L₀, χ_{eff} can be estimated from strong segregation theory according to L₀=1.1bN^{2/3} χ_{eff}^{1/6} where b is the average statistical segment length of the monomers comprising the BCP. The equal surface energy composition can then be determined via “hole-island” tests. Briefly, thin (t=1.75 L₀) films of the BCP are spin-coated on substrates that are preferential for one of the polymer. Atomic force microscopy (AFM) is used to image the surface topography of the films. BCPs with unequal surface energy exhibit step changes in height of thickness of 1L₀, while those with equal surface energy exhibit step changes in height with thicknesses of 0.5L₀. If the targeted value L₀ are not met, a new BCP can synthesized with a tuned value of N and Φ_{c} at Δγ=0.

While the above-described approach outlines a simple approach to estimate the thermodynamics of the BCPs, it may not provide quantitatively rigorous values of χ_{eff}. Further, any method of estimating determining that assumes a uniform sequence in each block, replaces the heterogeneity present in the B-r-C blocks (polypeptoid block) a “smeared-out” homogeneous block approximated through an averaged value of a. A single value of χ_{eff} also likely cannot describe both the resulting phase diagram, (parameterized by the product χeffN) as well as the density profile, characterized by the interface width, wₘ.

In some embodiments, to describe the phase behavior and self-assembly of copolymers in the high χ, low N limit, direct measurements of polymer properties that are most relevant to lithography: wₘ and line edge roughness (LER) are used. The parameter wₘ can be measured directly through resonant soft X-ray reflectivity (RSoXR) on supported nanostructured polymer thin films. RSoXR uses soft X-rays, typically near the carbon absorption edge (270-330 eV), to enhance the X-ray contrast between distinct polymers, which is quantified by the difference in the real and imaginary components of the X-ray scattering length density (SLD). The resulting reflectivity profiles are dependent on the thickness, roughness and SLD's of each component of the copolymer film and can resolve the polymer blocks within a lamellar block copolymer film.

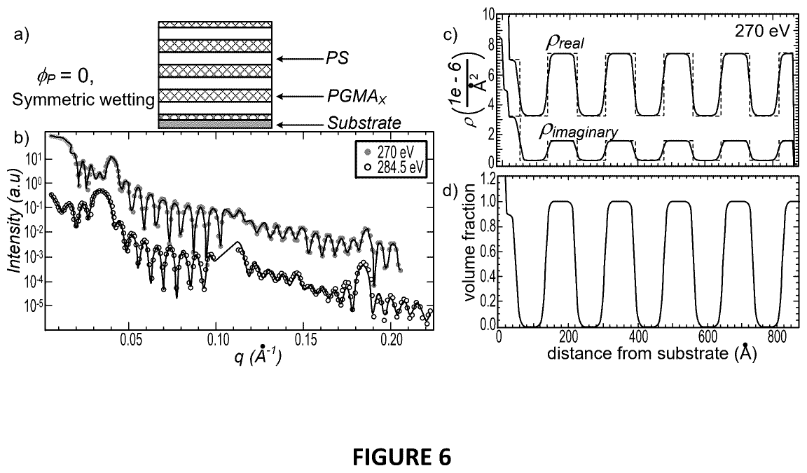

FIG. 6 shows an example of a RSoXR profile and structural information that can be obtained from reflectivity experiments. The reflectivity data show signatures of a multilayered structure with characteristic “multilayer peaks” of higher intensity that correspond to the periodicity of the BCP and high-frequency fringes corresponding to the total film thickness. The dampening in fringe intensity as a function of scattering vector, q, is related to the roughness or interfacial mixing between the polymer components of the nanostructured thin film. The measured interface width, wₘ, is determined by modeling the interface as an error function, and the width of the error function (σ) is then converted to wₘ according to wₘ=σ\sqrt{2π}.

The extent of mixing, characterized by a normalized interface width (wₘ/L0), serves as a more accurate thermodynamic description of A-b-(B-r-C) copolymers when compared to χ_{eff} calculated from SST. In embodiments of the methods described herein, the extent of mixing of a series of polypeptoid-based BCPs can determine how copolymer structure, characterized by φ_{C} and the conformational asymmetry between a polypeptoid block and other block of a BCP (e.g., polystyrene), affects the structure and thermodynamics of the copolymers.

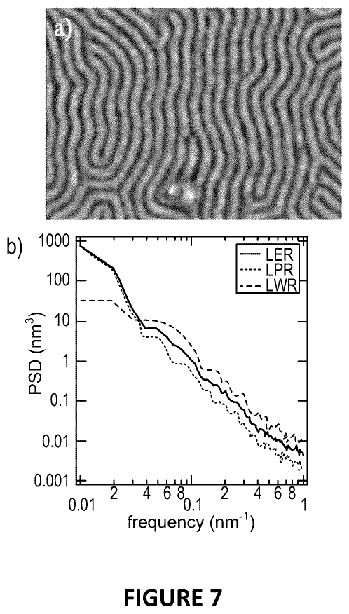

In some embodiments, a relationship between pattern roughness and thermodynamic properties such as χN and wₘ is determined. Thermodynamic fluctuations in copolymer melts can introduce structural changes to the block copolymer interface and subsequently affect pattern quality and roughness. In some embodiments, high resolution scanning electron microscopy (SEM) and subsequent image analysis are used calculate the line edge roughness (LER), line width roughness (LWR), and line placement roughness (LPR) of unaligned fingerprint patterns such as those shown in FIG. 7. By using high-temperature annealing, fingerprint patterns with large grain sizes can be generated. This allows pattern roughness metrics to be determined without having to align the polymer nanostructures via DSA.

Using solid-phase synthesis of polypeptoids allows complete control over N and the systematic tuning of χN by changing N alone. In some embodiments of the methods disclosed herein, a library of A-b-(B-r-C) copolymers with equal surface energy and varying N are synthesized. The extent of mixing via RSoXR is measured and can be compared to measured roughness values from fingerprint patterns. This enables direct comparison of wₘ with pattern roughness metrics such as LER, for BCPs with varying values of χN.

### Computation: Physics-Based Models and Machine Learning

The phase behavior and structure of conventional random block copolymers are difficult to describe using existing physics-based models. Existing models are mostly empirical in nature and utilize parameters such as the degree of polymerization N, an effective chemical compatibility χ_{eff}, and the statistical segment length b. While such models under ideal conditions can describe A-b-(B-r-C) copolymers by utilizing statistical averages of effective segment length b and mixing rules for χ_{eff}, systems with small degrees of polymerization and high degrees of incompatibility remain challenging. These difficulties only increase when attempting to predict and describe the properties of polypeptoid type polymers, whose properties have been demonstrated to depend on sequence and defy traditional polymer models. The specificity in these sequences, which are identical between all chains, lead to emergent properties not accounted for in existing polymer models.

In some embodiments, information alongside chemical identity and the χᵢⱼ between monomers of different types, rather than a χ_{eff} based on composition, is used to predict features such line edge roughness, surface energy, and lamellar period. Machine learning models may be used. The models can predict both the lamella interfacial width, with a preference towards narrower, smoother interfaces, and the surface energy Δγ between different domains. Due to sequence effects, both desired properties exhibit emergent that is suited to machine learning type models.

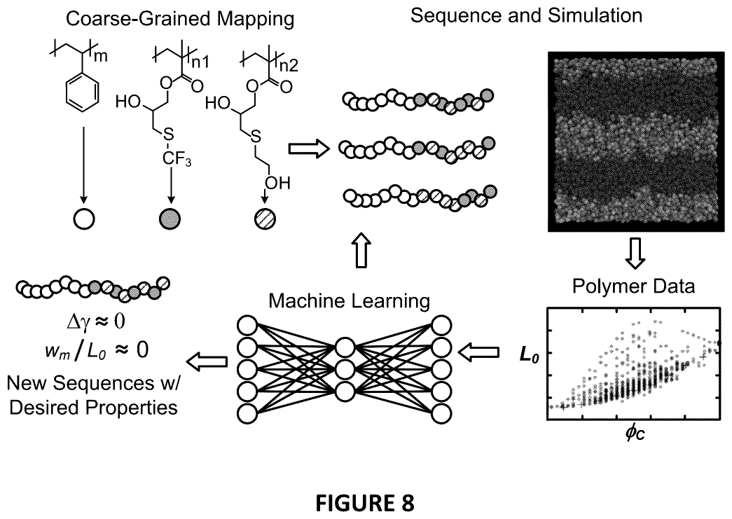

FIG. 8 shows an overview of the data flow from coarse-graining chemical species, simulation synthesis and data gathering, machine learning models and discovery of new peptoid sequences for EUV-DSA.

Machine learning requires large amounts of data to be effective and make accurate predictions. Such data may be gathered from large libraries of BCPs. However, in some embodiments if experimental data is limited, a data library using atomistic models and coarse-grained polymer simulations may be used. The coarse-grained models utilized may feature a soft dissipative dynamics type description, where each monomer unit is represented by one, two, or three beads to represent different monomer volumes. The original construction of the coarse-grained models (and the monomer characteristics) can rely on a mapping from atomistic simulations.

For example, chains in an A-(B-r-C) model can have 64 total monomers, with the first 32 being kept as simple single A type monomer beads throughout the data generation process, with the remaining 32 beads varied both in block fraction and sequence for B and C type beads. For each unique sequence the polymer behavior can be tested by for different χ_{AB}, χ_{AC}, and χ_{BC} parameters. Utilizing preassembled lamellar structures on a fixed substrate, the thickness and roughness can rapidly be equilibrated and measured, allowing for building a library of thousands of combined sequence and compatibilities to train the ML models. Due to the structure of polypeptoids as monodisperse, unique sequences, the correspondence between simulation and experiment may be particularly good due to elimination of polydispersity effects.

In some embodiments, the data generated is used to train a simple feed forward neural network. While this class of neural networks is among the simplest, they have shown good results predicting the properties of a variety of systems including polymers. Other machine learning techniques, including other neural networks, can be used. The neural network may be trained both to predict the interfacial width as well as the surface energy based upon only the sequence of monomers and their chemical identity. Experimental characterization data from real systems, including interfacial width and line edge roughness may also be fed to the model to increase accuracy. Similarly, results from fully atomistic simulations for a subset of the materials can be fed to the model.

In some embodiments, once sufficient data is accumulated to make accurate predictions with the feed forward network, an additional ML model to perform inverse design and given the desired input of near zero Δγ and narrow interfacial width can be trained. This can output potential combinations of sequence and chemical compatibility that will achieve these values. In some embodiments, these sequences may then be synthesized experimentally into real polypeptoid materials that exhibit the desired properties. The inverse design of polypeptoid molecules with desired properties as described will be advantageous in polymeric materials development. For example, as a result of the precise control of the block structure, one can for example make a peptoid segment with the “click” group in the center of the peptoid and very different segments on either side. This effort affords new methods of tuning interface energies and curvature. The described computational methods can help guide a molecular design effort prior to synthesis.

### DSA of BCPs and Characterization of Assembled Structures

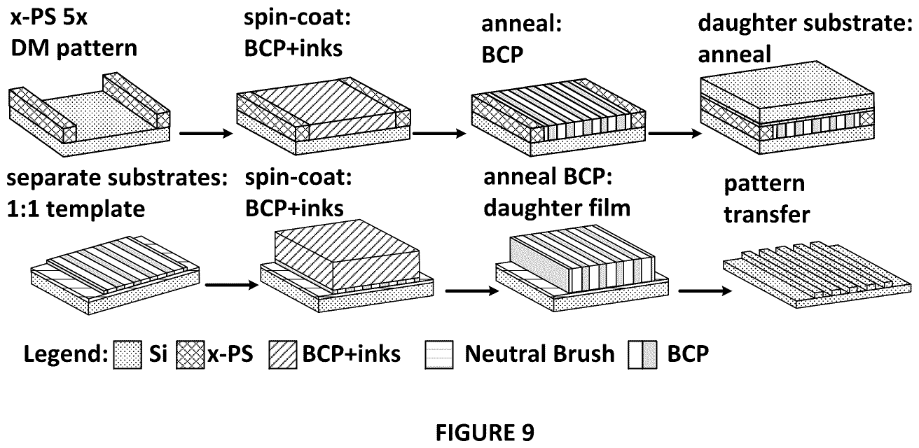

Patterns to guide the assembly of peptoid-based BCPs can be generated using lithographic techniques such as EUV or by molecular transfer printing (MTP) techniques. In MTP, the BCP pattern is loaded with homopolymer “inks” made of hydroxyl-terminated polymer brushes, which can graft to the Si substrate and template the pattern on a daughter substrate. BCPs loaded with homopolymer inks are able to register patterns at pitches as low as 28 nm. In addition, the presence of the homopolymer inks does not increase the roughness of the resulting polymer patterns. Polypeptoids with a terminal hydroxyl or dopamine units for surface functionalization may be used as the homopolymer inks, which form dense brushes on surfaces. Pattern transfer into the Si substrate can then be conducted on the daughter polymer patterns. SIS or a “dry liftoff” technique can be used for pattern transfer. FIG. 9 shows an example of MTP and pattern transfer. In FIG. 9, a first BCP+ink film is spin coated onto a substrate having a pattern thereon. As indicated in the Figure, in the example of FIG. 9, the pattern (formed e.g., from a PS brush) is 5× less dense than the BCP. Annealing guides the self-assembly of the BCP between the constraints of the pattern. This may also be referred to as “inducing” assembly of the BCP and can involve any appropriate method including thermal anneal, solvent anneal, etc. The result is a microphase-separate film having ink molecules appropriately segregated into one of the domains. A second “daughter substrate” having a brush neutral to the blocks of the BCP is placed into contact with the BCP and the patterned transferred to the brush. This can involve mass transfer of the ink molecules to the second substrate. The daughter substrate is chemically patterned in accordance with the pattern at the free surface of the BCP+ink, in this case stripes or lamellae. A second BCP film can then be disposed on the pattern with that pattern transferred to the daughter substrate.

High resolution SEM and image analysis can be used to determine the LER/LWR/LPR of the resulting of the polymer pre-pattern and Si pattern following pattern transfer. The 3D structures can be further characterized with critical dimension resonant soft X-ray scattering (res-CDSAXS) and reconstructed through application of previously derived 3D models for perpendicular lamellar structures. This enables visualization of the polymer pattern throughout the depth of the films to analyze how the guiding pattern affects the self-assembly at the bottom of the film.

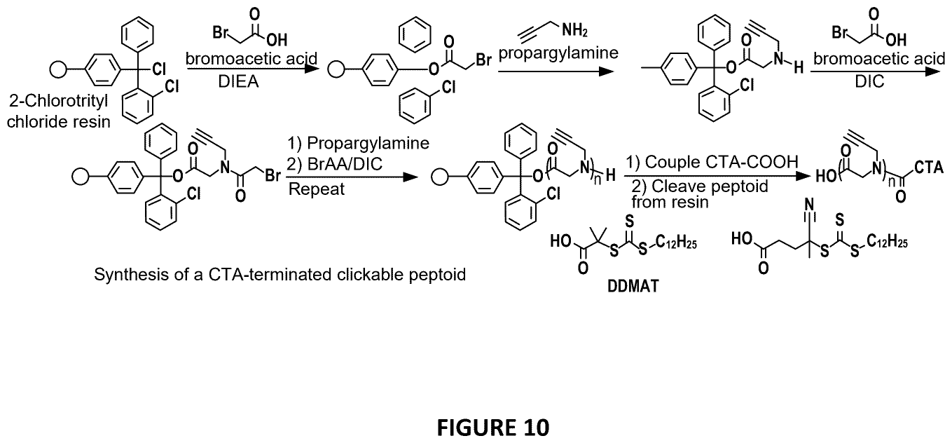

While the example of FIG. 10 shows a BCP assembled with a free surface, the methods described herein may be used with workflows that use BCPs assembled between two condensed-phase surfaces, with wetting behavior optimized for the interfacial energy of the BCPs blocks with the overlying condensed phase surface.

### EXAMPLE

FIG. 10 shows an example of a peptoid macro-CTA synthesis. Ten repeat units of an alkyne side chain that was end-functionalized with a RAFT CTA were synthesized. The alkyne side chain has click chemistry functionalization after synthesis, including a quantitative CuAAC reaction. After synthesis of a 10-mer of the propargylamine-based peptoid, two CTAs were explored to couple with an amine chain end based on examples reported in prior peptide macro-CTA literature: 2-(dodecylthiocarbonothioylthio)-2-methylpropionic (DDMAT)43 and 4-cyano-4-[(dodecylsulfanylthiocarbonyl)sulfanyl]pentanoic acid (CDTPA). Three coupling conditions (DIC; HCTU/DIEA; and DIC/DMAP) and three cleavage conditions (5% TFA, 5% TIS, 90% DCM; 20% HFIP, 80% DCM; and 2% TFA, 98% DCM) were examined for both CTAs, and the efficacy of these reactions were assessed via HPLC-MS.

Of the 18 combinations, all conditions to couple DDMAT were unsuccessful. This may be due to the added steric bulk associated with the N-substituted group directly adjacent to the site of coupling of the also sterically encumbered DDMAT. Of the remaining 9 combinations with CDTPA, 4 such combinations showed successful coupling and cleavage.

Trithiocarbonate CTA for these tests are more stable to nucleophiles than dithiobenzoates. Cleavage conditions that safely maintain the CTA functionality were assessed. One combination (HCTU/DIEA coupling, TFA/TIS cleavage) exhibited complete hydrolysis of the CTA, two combinations (DIC coupling, TFA/TIS cleavage; DIC coupling, TFA cleavage) contained mixtures of hydrolyzed and unhydrolyzed CDTPA, and one set of conditions (HCTU/DIEA coupling, TFA cleavage) contained the peptoid macro-CTA in its unhydrolyzed form. Accordingly, certain embodiments may use this set of conditions during synthesis of peptoid macro-CTAs.

Although the foregoing invention has been described in some detail for purposes of clarity of understanding, it will be apparent that certain changes and modifications may be practiced within the scope of the invention. It should be noted that there are many alternative ways of implementing both the process and compositions of the present invention. Accordingly, the present embodiments are to be considered as illustrative and not restrictive, and the invention is not to be limited to the details given herein.

1. A method comprising:
forming a BCP system comprising A-(B-r-C) block copolymer (BCP) molecules, the BCP molecules each including an A block and a (B-r-C) block, wherein the (B-r-C) block is a polypeptoid copolymer;
wherein surface energies of the A and (B-r-C) blocks are commensurate with each other such that the BCP system can assemble in a thin film with non-preferential wetting of domains of the A and (B-r-C) blocks at the surface or interface of the thin film.

2. The method of claim 1, wherein the A block is a peptoid.

3. The method of claim 1, wherein the A block is a non-peptoid.

4. The method of claim 1, further comprising using a machine learning model to predict an interfacial width of an assembled thin film and surface energies based on only the sequence of monomers and their chemical identities.

5. The method of claim 4, further comprising training the machine learning model.

6. The method of claim 1, wherein the BCP system is characterized by having a dispersity Ð_{M}=M_{w}/Mₙ of no more than 1.00.

7. The method of claim 1, wherein the surface of the thin film contacts a vacuum or gas.

8. The method of claim 1, wherein the surface of the thin film contacts a solid or liquid.

9. The method of claim 1, further comprising providing a patterned substrate to guide the assembly of the thin film.

10. The method of claim 9, further comprising spin coating a solution comprising the BCP system on the patterned substrate and inducing directed self-assembly of the thin film with non-preferential wetting of domains of the A and (B-r-C) blocks at the surface or interface of the thin film.

11. The method of claim 10, further comprising transferring a pattern from the thin film to the substrate.
